(19) United States
(12) Patent Application Publication
(10) Pub. No.: US 2026/0063737 A1
(43) Pub. Date: Mar. 5, 2026

(54) EMERGENCY STOP ASSEMBLY FOR MRI SCANNER

(71) Applicant: GE Precision Healthcare LLC, Waukesha, WI (US)

(72) Inventors: Michael Smith, Waukesha, WI (US); Jeff Johnson, Greenfield, WI (US)

(73) Assignee: GE Precision Healthcare LLC, Waukesha, WI (US)

(21) Appl. No.: 18/825,737

(22) Filed: Sep. 5, 2024

(51) Int. Cl. G01R 33/28

(52) U.S. Cl. CPC G01R 33/288

(57) ABSTRACT

An arrangement for an imaging scanner, such as an MRI scanner, to position an emergency stop assembly on the scanner. The scanner includes a front cover having an inner and an outer surface. A receiving plate is mounted to the inner surface of the front cover. A locking bracket is coupled to the emergency stop assembly. The locking bracket is positioned on the receiving plate and rotated relative to the receiving plate to move between a release position and a locking position. The locking bracket includes engagement flanges that are received and retained in receiving slots of the receiving plate. A locking assembly is position adjacent to the receiving plate and is operable between engaged and disengaged positions. In the engaged position, the locking assembly prevents movement of the locking bracket away from the locking position. A method is provided for mounting the emergency stop assembly to the imaging scanner.

### BACKGROUND

The present disclosure generally relates to an emergency stop assembly for an MRI scanner. More specifically, the present disclosure relates to a mounting arrangement to removably mount the emergency stop assembly on an MRI scanner without having to fully remove the front cover of the MRI scanner.

MRI scanners are constructed with a very large, powerful magnet assembly. As a result, it is mandated that the MRI scanner must include an emergency stop (estop) assembly that can be actuated by a user to immediately interrupt power to the magnet should any problem exist that requires immediate intervention. The emergency stop assembly in currently available MRI scanners includes an emergency stop button that extends through a portion of the front cover of the MRI scanner in one or more locations such that a user can quicky access the emergency stop button if needed during an MRI procedure.

In order to remove or replace the emergency stop assembly, a user must typically remove the entire front cover of the MRI scanner or a substantial bezel portion of the front cover. Recently, there has been an increased desire to create an MRI scanner with a unitary front cover to enhance the overall look and appearance of the MRI scanner. Since a unitary front cover can be very large, heavy and thus hard to remove, a need has arisen for an improved method and system for mounting the emergency stop assembly on the MRI scanner. Such mounting must present the stop button of the emergency stop assembly to the clinician in a similar manner to currently available MRI scanners.

The inventors recognized the need for a system and method of mounting an emergency stop assembly in a way that the emergency stop assembly can be mounted and removed without having to remove the entire front cover of the MRI scanner. The present disclosure provides an improved system and method for mounting the emergency stop assembly to the inner surface of the front cover without having to remove the entire front cover during replacement or initial installation.

### SUMMARY

This Summary is provided to introduce a selection of concepts that are further described below in the Detailed Description. This Summary is not intended to identify key or essential features of the claimed subject matter, nor is it intended to be used as an aid in limiting the scope of the claimed subject matter.

In one embodiment of the present disclosure, an arrangement is provided for an imaging scanner, such as an MRI or CT scanner, having a unitary front cover including an outer surface and an inner surface and one or more display screens. The arrangement includes a receiving plate that is securely attached to the inner surface of the front cover. The receiving plate is accessible to a user when the front cover is mounted to the outer housing of the imaging scanner. The receiving plate includes a plurality of receiving slots that are spaced around the outer circumference of the receiving plate. The arrangement further includes an emergency stop assembly that is configured to communicate with the controls of the imaging scanner. The emergency stop assembly includes a stop button that can be operated to cause the emergency stop assembly to initiate an emergency stop procedure. The emergency stop assembly including the stop button allows the user to initiate the stop procedure externally relative to the front cover of the imaging scanner.

The arrangement further includes a locking bracket that is coupled to the emergency stop assembly. The locking bracket is designed to be received by the receiving plate such that the locking bracket can be used to mount the emergency stop assembly to the receiving plate. The locking bracket is configured to be rotatable relative to the stationary receiving plate between a release position and a locking position. In the locking position, the emergency stop assembly is held in place on the receiving plate and in the release position, the emergency stop assembly can be removed from the inner surface of the front cover. The locking bracket includes a plurality of engagement flanges that are each received and retained by the receiving plate when the locking bracket is rotated into the locking position. The receiving plate includes a plurality of receiving slots that are each sized to receive one of the engagement flanges on the locking bracket when the locking bracket is rotated into the locking position.

In one embodiment, the arrangement includes a locking assembly that is positioned adjacent to the receiving plate and is operable to engage the locking bracket to prevent rotation of the locking bracket from the locking position. When the locking assembly in in a disengaged position, the locking bracket is able to rotate relative to the stationary receiving plate such that the locking bracket can move to a release position. The locking assembly is thus movable between the engaged and disengaged positions to control the ability to remove the locking bracket from the receiving plate mounted to the inner surface of the front cover.

The locking bracket can include at least one locking arm in addition to the plurality of engagement flanges. The locking assembly is positioned to engage the locking arm when the locking assembly is in the engaged position to prevent rotation of the locking bracket from the locking position. In one exemplary embodiment, the locking arm includes a tab that depends from the locking arm. The tab is located adjacent to the locking assembly when the locking bracket is in the locking position. In one exemplary embodiment, the locking assembly includes a set screw that is received in the tab to prevent rotation of the locking bracket.

In another embodiment of the present disclosure, an imaging scanner, such as an MRI or CT scanner, is provided that includes a front cover having an outer surface and an inner surface. The imaging scanner can include one or more display screens that are viewable and accessible from the outer surface of the front cover. A receiving plate is securely attached to the inner surface of the front cover and is accessible without having to remove the entire front cover of the imaging scanner. The receiving plate includes a plurality of receiving slots that are equally spaced around the receiving plate. The imaging scanner further includes an emergency stop assembly that is configured to communicate with the controls of the imaging scanner. The emergency stop assembly includes a stop button that can be operated by a user to cause the emergency stop assembly to initiate an emergency stop procedure.

The imaging scanner further includes a locking bracket that is coupled to the emergency stop assembly. The locking bracket is designed to be removably received by the receiving plate such that the locking bracket can be used to mount the emergency stop assembly to the inner surface of the front cover, and specifically to the receiving plate. The locking bracket is configured to be rotatable relative to the stationary receiving plate between a release position and a locking position. The locking bracket includes a plurality of engagement flanges that are each received and retained by the receiving plate when the locking bracket is rotated into the locking position. The receiving plate includes a plurality of receiving slots that are each sized to receive one of the engagement flanges on the locking bracket when the locking bracket is in the locking position.

In one embodiment, the imaging scanner further includes a locking assembly that is positioned adjacent to the receiving plate. The locking assembly is operable between an engaged position in which the locking assembly engages the locking bracket to prevent rotation of the locking bracket from the locking position. When the locking assembly is in a disengaged position, the locking bracket is able to rotate relative to the stationary receiving plate such that the locking bracket can be removed from contact with the receiving plate.

The locking bracket can include at least one locking arm in addition to the engagement flanges. The locking assembly engages the locking arm to prevent rotation of the locking bracket when the locking assembly is in the engaged position. In one exemplary embodiment, the locking arm includes a tab and the locking assembly includes a set screw that is received in the tab to prevent rotation of the locking bracket.

The present disclosure is further directed to a method of mounting an emergency stop assembly, including a stop button, to an imaging scanner, such as an MRI scanner, that includes a front cover having an outer surface and an inner surface. The front cover of the MRI scanner is a unitary element and is mounted to the outer housing of the MRI scanner. The MRI scanner can include one or more display screens and an internal control system for controlling the operation of the MRI scanner in a known manner. The method includes the step of initially attaching a receiving plate to the inner surface of the front cover. The receiving plate is located in a position on the inner surface of the front cover such that the receiving plate can be accessed without having to remove the entire front cover. A locking bracket is mounted to the emergency stop assembly prior to installation of the emergency stop assembly on the MRI scanner.

Once the locking bracket is installed on the emergency stop assembly, the emergency stop assembly is positioned behind the front cover and in contact with the receiving plate that is mounted to the inner surface of the front cover. Once in this position, the emergency stop assembly and locking bracket are rotated into a locking position in which the locking bracket engages the receiving plate to hold the emergency stop assembly on the receiving plate.

During the installation of the receiving plate on the inner surface of the front cover, the receiving plate is aligned with an access opening in the front cover. When the locking bracket is received by the receiving plate, the stop button of the emergency stop assembly extends into the access opening formed in the front cover and is accessible from the outer surface. In one exemplary embodiment, a locking assembly in installed and attached to the inner surface of the front cover adjacent to the receiving plate. The locking assembly is operable to move to an engaged position in which the locking assembly engages the locking bracket to prevent rotation of the locking bracket away from the locking position. When the locking assembly is moved to a disengaged position, the locking bracket is released and can rotate away from the locking position to a release position. The locking bracket is configured to include at least one locking arm and the locking assembly engages the locking arm to prevent rotation of the locking bracket. The locking arm can include a tab that is engaged by a set screw of the locking assembly.

When the locking bracket and emergency stop assembly are located on the receiving plate, rotation of the locking bracket in a first direction moves the locking bracket into a locking position while rotation on an opposite, second direction moves the locking bracket into a release position. Prior to installing the emergency stop assembly, the display of the MRI scanner is removed to provide access to the receiving plate mounted to the inner surface of the front cover of the MRI scanner.

Various other features, objects, and advantages of the invention will be made apparent from the following description taken together with the drawings.

### BRIEF DESCRIPTION OF THE DRAWINGS

The present disclosure is described with reference to the following Figures.

FIG. 1 is a front perspective view of an MRI scanner in accordance with the present disclosure;

FIG. 2 is a magnified view of the location of an emergency stop button of a prior art MRI scanner;

FIG. 3 is a magnified view of the location of an emergency stop button of the MRI scanner of the present disclosure;

FIG. 4 is a view showing the removal of the display and shroud to provide access to the receiving plate mounted to an inner surface of the front cover of the MRI scanner;

FIG. 5 is a back view of the front cover showing the mounting of the receiving plate;

FIG. 6 is a magnified view of the receiving plate shown in FIG. 5;

FIG. 7 is a top view of the emergency stop assembly with the locking bracket mounted thereto;

FIG. 8 is a side view of the emergency stop assembly with the locking bracket mounted thereto;

FIG. 9 is an exploded view of the emergency stop assembly and locking bracket;

FIG. 10 is a view of the emergency stop assembly and the locking bracket in a release position relative to the receiving plate;

FIG. 11 is a view of the emergency stop assembly and the locking bracket in a locking position relative to the receiving plate with a locking assembly disengaged; and

FIG. 12 is a view of the emergency stop assembly and the locking bracket in a locking position relative to the receiving plate with a locking assembly engaged.

### DETAILED DESCRIPTION

The present inventors have recognized several problems with the mounting of emergency stop assemblies with MRI scanners that include a unitary front cover that is large in size, heavy and thus difficult and time consuming to remove. When the emergency stop assembly needs to be removed and replaced, or during the initial assembly of the MRI scanner, it is difficult to gain access to an inner surface of the front cover without removing the entire front cover from the housing of the MRI scanner. In prior art MRI scanners, the emergency stop assembly is typically mounted somewhere behind the front cover or a removable bezel portion of the front cover. The present disclosure was developed by the inventors to improve the mounting and access to the emergency stop assembly by mounting a receiving plate to the inner surface of the front cover and designing the receiving plate to receive the emergency stop assembly and lock the emergency stop assembly into a locked position. Although the present disclosure shows the use of the receiving plate and locking bracket to mount an emergency stop assembly on the front cover of an MRI scanner, the present disclosure could also be used with other imaging scanners that have a large front cover that is difficult to remove, such as a CT scanner. The terms imaging scanner, MRI scanner and CT scanner will be used throughout the disclosure to refer to imaging scanners that can utilize the subject matter of the present disclosure.

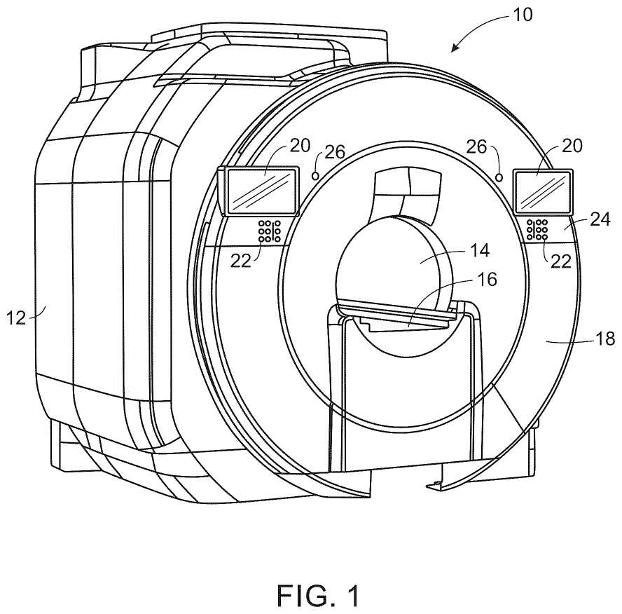

FIG. 1 illustrates an MRI scanner 10 constructed in accordance with the present disclosure. The MRI scanner 10 includes a main housing 12 that surrounds the magnet, gradient coils and radio frequency coils of the scanner 10. The MRI scanner 10 includes a central bore 14 that provides access to the interior of the scanner 10 for receiving the patient being scanned. A patient table 16 is movable into and out of the central bore 14 to position the patient in the correct location for the scanning procedure.

The MRI scanner 10 of the present includes a front cover 18 that provides a desirable appearance for the entire scanner 10. The front cover 18 has a central opening aligned with the central bore 14 such that the patient can pass through the front cover 18. In the embodiment shown, the front cover 18 is a single piece of material that is removed from the housing 12 as a single element. Since the front cover 18 has a relatively large size and has a substantial weight, removal of the unitary front cover 18 from the main housing 12 may require more than one person and is both difficult and time consuming. Although the present disclosure shows the front cover of an MRI scanner, the present disclosure could also be used with other types of imaging scanners that have a large front cover that is difficult to remove, such as a CT scanner. The term MRI scanner will be used throughout the disclosure but it should be understood that the concept of the present disclosure could be used with other types of imaging scanners, such as a CT scanner that are not specifically shown in the Figures.

The front cover 18 shown in FIG. 1 supports a pair of displays 20 that present scanning information to the clinician using the MRI scanner 10 and allows the clinician to control various operating parameter that allow the clinician to carry out an MRI procedure. In the embodiment shown, a control panel having series of control buttons 22 is located below each of the displays 20 to allow the clinician to enter commands and select options related to the operation of the MRI scanner 10. Both the display 20 and the control panel buttons 22 included as part of a shroud 24 that is mounted within a recessed access area formed as part of the front cover 18. In the embodiment shown, a display 20 and the control panel including the series of buttons 22 are located on both sides of the central bore 14 such that a clinician can operate the MRI scanner 10 from either side of the central bore 14. It is contemplated that certain MRI scanners 10 could include only one display 20 and only a single control panel including the buttons 22.

Because of the nature of operation of the MRI scanner 10, the MRI scanner 10 is required to include an emergency stop button 26 that can be depressed by the clinician to immediately interrupt the power supply to the internal magnet of the MRI scanner 10. The emergency stop button 26 is formed as part of a larger emergency stop (estop) assembly. When the emergency stop button 26 is depressed, the emergency stop assembly immediately communicates with the internal operating system of the MRI scanner 10. The internal operating system of the MRI scanner is designed such that when the emergency stop button 26 is depressed, power is immediately disconnected from the magnet of the MRI scanner 10 and other emergency procedures are initiated. The details of the emergency procedures taken upon depression of the emergency stop button 26 can vary depending on the specific MRI scanner 10 and are known to those skilled in the art. In addition, in different types of imaging scanners, such as CT scanners, the emergency stop assembly communicates to the internal operating system of the imaging scanner such that the operating system can take emergency action upon depression of the emergency stop button 26.

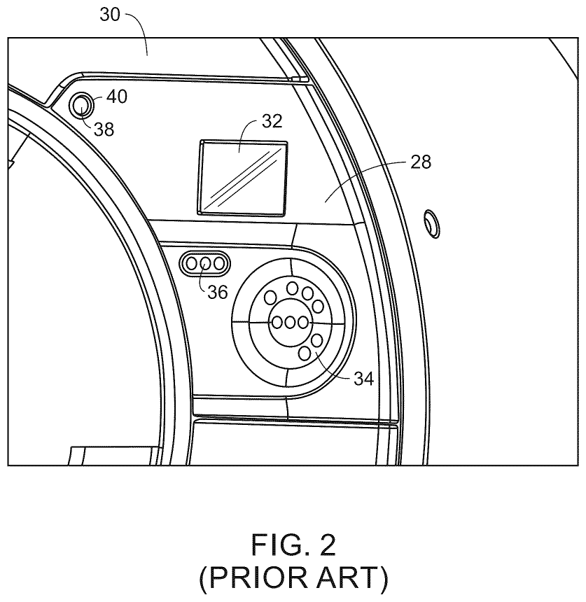

FIG. 2 illustrates a prior art MRI scanner that is shown for comparison to the MRI scanner 10 of the present disclosure. The prior art MRI scanner shown in FIG. 2 includes a larger front bezel 28 that is positioned in an open area of the prior art front cover 30. In the prior art embodiment, the front bezel 28 supports a variety of hardware, such as the display 32, control panel 34 and control buttons 36. The emergency stop button 38 extends into an access hole 40 formed in the front bezel 28. The emergency stop button 38 is slightly recessed (approximately 1 mm) from the front surface of the front cover 30 to prevent accidental depression. In the embodiment shown, the emergency stop assembly including the emergency stop button 38 is mounted to either the front bezel 28 or internal frame elements of the MRI scanner. In the prior art embodiment, since a variety of hardware is attached directly to the front bezel 28, it is cumbersome to remove the front bezel 28 to gain access to the emergency stop assembly that includes the emergency stop button 38. The weight of the combined hardware attached to the front bezel 28 makes gaining access to the emergency stop assembly inconvenient and difficult. Thus, the design of the present disclosure was created to provide better access to the emergency stop assembly.

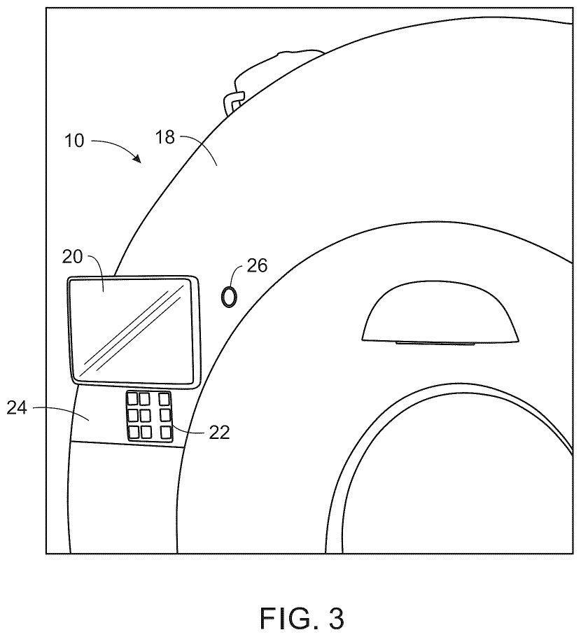

FIG. 3 is a magnified view of the MRI scanner 10 constructed with one embodiment of the present disclosure. As shown, the display 20 and the control panel including the control buttons 22 are located in an area of the front cover that includes the removable shroud 24. During assembly or maintenance on the MRI scanner 10, the display 20 can initially be removed and the shroud 24 then removed from the front cover 18 to provide access to the inner surface of the front cover 18. When the display 20 and the shroud 24 are removed, access is provided to the space behind the front cover and to the inner surface of the front cover 18.

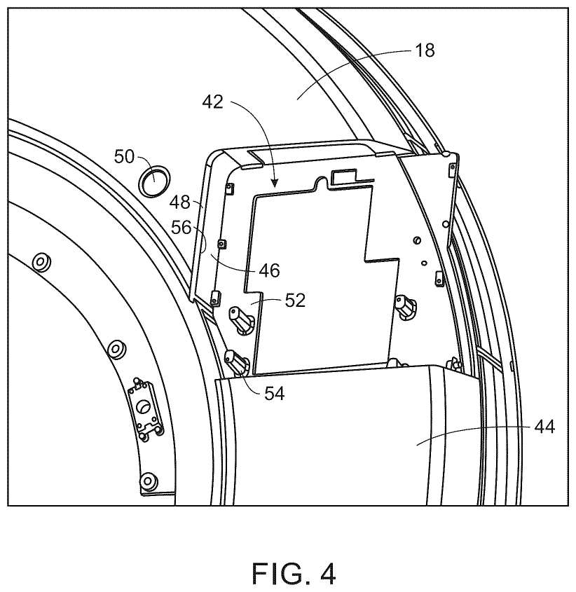

FIG. 4 is a view of the front cover 18 with the display, control panel and shroud removed. When the display and the shroud are removed, an access area 42 is exposed. The access area 42 is recessed from the outer surface 44 of the front cover 18. The access area 42 creates an area that allows for connections between the internal control system of the MRI scanner and the display and the control panel. The access area 42 includes a side opening 46 that allows a user to reach behind the front wall 48 of the front cover 18 to access the inner surface 56 of the front wall 48. As shown in FIG. 4, the front wall 48 includes an access opening 50 that located near the side opening 46 such that a user can reach behind the front cover to reach the access opening 50. The access opening 50 is sized to allow the emergency stop button to be accessible through the front wall 48 to allow an operator to depress the emergency stop button if needed. As indicated previously, the emergency stop button is slightly recessed from the outer surface 44 of the front cover 18 to prevent accidental depression of the stop button.

The spacing between the front wall 48 and the mounting surface 52 is sufficient to allow the user to reach his or her hand behind the front wall 48 and install and/or remove the emergency stop assembly in a manner to be described in greater detail below. In the embodiment shown, the access area 42 includes a series of standoffs 54 that provide both support and a point of attachment for the display 20. When the display 20 is removed as shown, the standoffs 54 are positioned to provide access to the side opening 46. Although FIG. 4 illustrates the access area 42 to the right side of the central bore, it should be understood that an identical access area is included in the front cover 18 on the other side of the central bore. The access area on the opposite side of the front cover 18 is a mirror image of the access area 42 shown in FIG. 4.

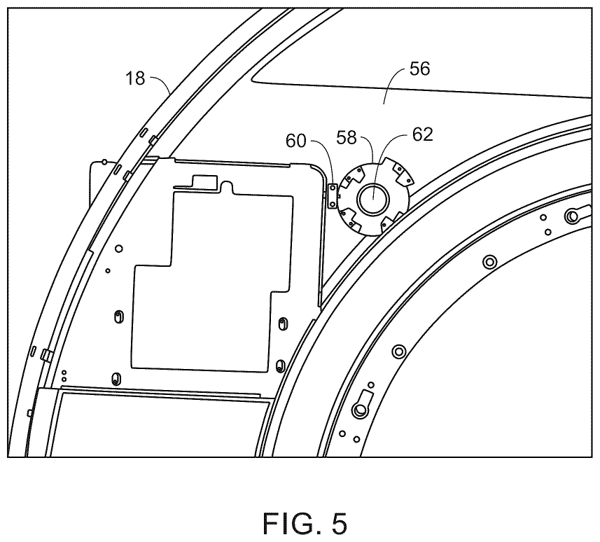

FIG. 5 is a back view of the front cover 18 and shows the inner surface 56 of the front cover 18. When the front cover 18 is mounted to the outer housing of the MRI scanner, the inner surface 56 faces toward the interior of the scanner and is thus not visible or generally accessible to a user. The inner surface 56 of the front cover 18 serves a mounting surface for a receiving plate 58 and a locking assembly 60 in accordance with the present disclosure. The receiving plate 58 and the locking assembly 60 are designed to secure and lock the emergency stop assembly in place on the inner surface 56 of the front cover 18 in alignment with the access opening 50 that extends through the front wall 48 of the front cover 18 as was shown and described with reference to FIG. 4. The receiving plate 58 includes a central opening 62 that is aligned with the access opening 50 and thus provides access to the outer surface of the front cover 18.

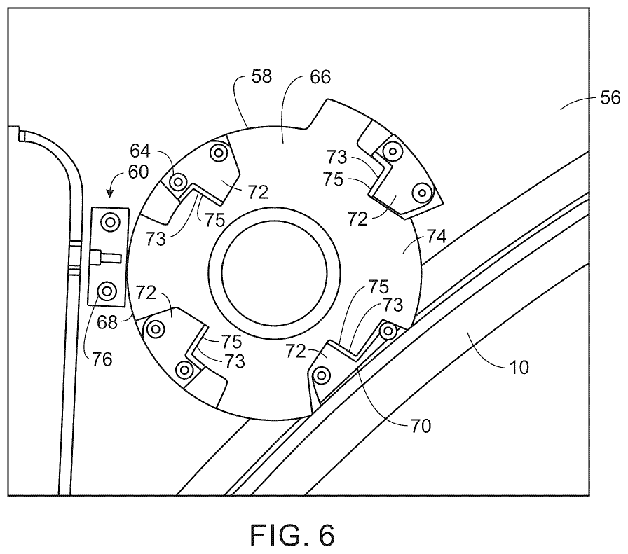

FIG. 6 is a magnified view of the receiving plate 58 constructed as part of the exemplary embodiment of the present disclosure. In the embodiment shown, the receiving plate 58 is formed from a metallic material and is attached to the inner surface 56 by a series of connectors 64. The receiving plate 58 includes a generally planar body portion 66 that has a generally circular outer edge 68. The outer edge 68 of the receiving plate 58 includes a flat side surface 70 that is generally aligned with a portion of the front cover that is closest to the center opening of the front cover. The receiving plate 58 includes a series of ears 72 that are set off and spaced above the top surface 74 of the body portion 66 to define receiving slots 73 between the ears 72 and the planar body portion 66. The series of ears 72 are equally spaced around the outer circumference of the receiving plate 58 and each include a leading edge surface 75. The leading edge surfaces 75 are each oriented in the same direction. The leading edge surfaces 75 define the entrance to the receiving slots 73 created between the ear 72 and the top surface of the body portion 66. The receiving slots 73 are positioned and sized such that the receiving plate 58 can receive the emergency stop assembly in a manner to be described below.

The receiving plate 58 is designed such that the receiving plate 58 can be installed on either side of the center opening of the front cover 18. As was discussed above, each side of the front cover includes the same operating components such that the MRI scanner can be controlled and operated from either side of the central bore. Such configuration is common with other types of imaging scanners, such as CT scanners, in which the scanner can be operated from either side of the patient. When the receiving plate 58 is used on the opposite side of the front cover, the receiving plate 58 is rotated such that the flat side surface 70 faces the center opening in the same manner as shown in FIG. 6.

In addition to the receiving plate 58, the locking assembly 60 is also mounted to the inner surface 56 of the front cover. The locking assembly 60 is secured to the inner surface 56 by a series of connectors 76. The locking assembly 60 is located adjacent to the outer edge surface 68 of the receiving plate 58 such that the locking assembly 60 can engage the emergency stop assembly when the emergency stop assembly is received on the receiving plate 58 as will be described below. In the embodiment shown, the locking assembly 60 is a manually activated assembly and does not need any connection to the control system of the MRI scanner. However, it is also contemplated that the locking assembly could be controlled by the control system of the MRI scanner in alternate embodiments.

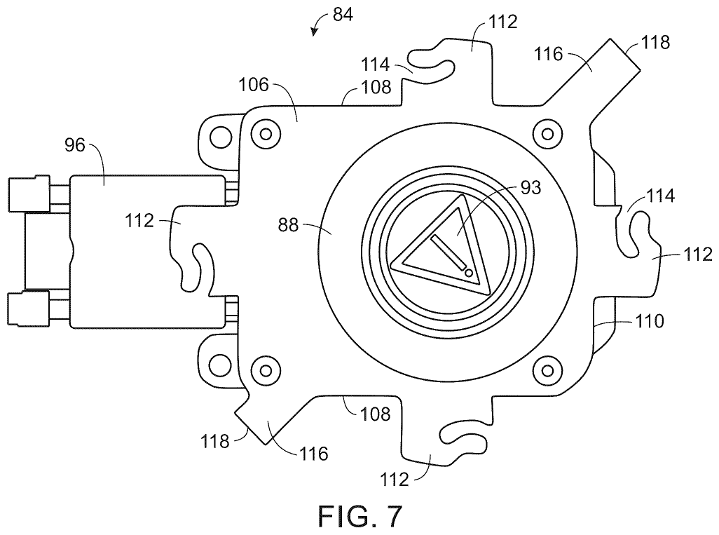

FIGS. 7-9 illustrate the emergency stop assembly 82 and locking bracket 84 constructed in accordance with the present disclosure. The emergency stop assembly 82 is a commercially available assembly that has been used in previously available imaging scanners, such as MRI scanners and CT scanners, to communicate a desire for an emergency stop procedure. In accordance with the present disclosure, it is desirable to mount the emergency stop assembly 82 to the inner surface of the front cover of the MRI scanner and in the position shown in the preceding Figures to provide a signal to the MRI scanner when depressed such that the control system of the MRI scanner can modify the operation of the MRI scanner.

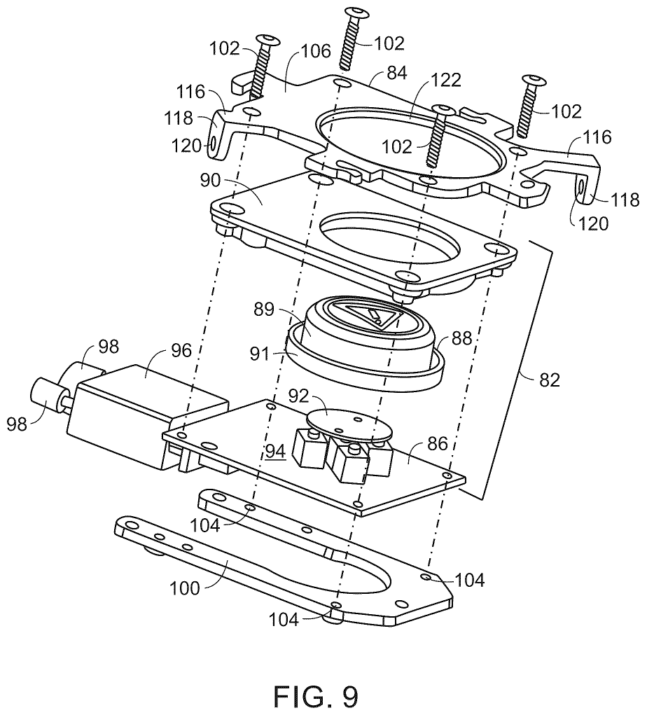

As best shown in the exploded view of FIG. 9, the emergency stop assembly 82 includes a control board 86, a stop button 88 and a top housing 90 that are joined to each other. The stop button 88 includes a flexible center portion 89 and an outer rim 91. The outer rim 91 supports the stop button 88 on the control board 86. The flexible center portion 89 includes a symbol 93 that provides a visual cue to the user of the function of the stop button 88. Further, the stop button 88 is typically of a very bright color, such as red or orange, that provides another indication of the function of the emergency stop button. The flexible center portion 89 is positioned above an activation plate 92 that rests upon a series of switches 94 supported on the control board 86. When the stop button 88 is supported on the control board 86, the center portion 89 is located slightly above the activation plate 92. If a force is applied to the stop button 88, the center portion 89 pushed down on the activation plate 92, which depresses one or more of the switches 94 to signal that the stop button 88 was depressed by the user.

The control board 86 is connected to a communication module 96 that includes a series of communication connections 98 that allow the communication module 96, and thus the stop button 88, to communication with the internal control system for the MRI scanner. The series of communication connections 98 can take the form of any type of plug that can be connected to control wires in a mating plug included as part of the MRI scanner. During the installation of the emergency stop assembly 82, the mating plugs on the MRI scanner and the communication connections 98 are mated to create the communication link between the MRI scanner and the communication module 96. Likewise, when the emergency stop assembly 82 is removed, the plug connection between the control wires of the MRI scanner is disconnected from the communication connections 98.

In accordance with the present disclosure, the locking bracket 84 is attached to the emergency stop assembly 82 to provide a mounting configuration for the emergency stop assembly. In the embodiment shown, the locking bracket 84 combines with an attachment bracket 100 to sandwich the assembled emergency stop assembly 82 between the two brackets 84 and 100. A series of threaded connectors 102 extend through aligned holes in the locking bracket 84, the top housing 90 and the control board 86 and are received in receiving holes 104 in the attachment bracket 100. In this manner, the locking bracket 84 is securely attached to and is movable with the entire assembled emergency stop assembly 82. It is contemplated that the locking bracket 84 could be attached to the assembled emergency stop assembly in a different manner. However, it is important that the locking bracket 84 is secured to and movable with the emergency stop assembly 82.

FIG. 7 illustrates the configuration of the locking bracket 84 that is attached to the emergency stop assembly 82. The locking bracket 84 of the present disclosure includes a generally rectangular main body section 106 having a pair of spaced side edges 108 and a pair of spaced end edges 110. Each of the spaced side edges 108 and the spaced end edges 110 include an engagement flange 112 that extends past the respective edge of the main body section 106. As illustrated, the engagement flanges 112 are spaced from each other at 90° intervals around the circular stop button 88 that extends through the center of the main body section 106. Each engagement flange 112 includes a receiving channel 114 that extends into the engagement flange 112. The receiving channel 114 is designed to engage a post or standoff to lock the engagement flange 112 in a desired position. The openings to each of the receiving channels 114 extend in the same rotational direction such that when the locking bracket 84 is rotated in the counterclockwise direction when viewed from above as in FIG. 7, a post or stand off can enter into the receiving channels 114 while rotation in the opposite, clockwise direction would remove the post or stand off from the receiving channel 114.

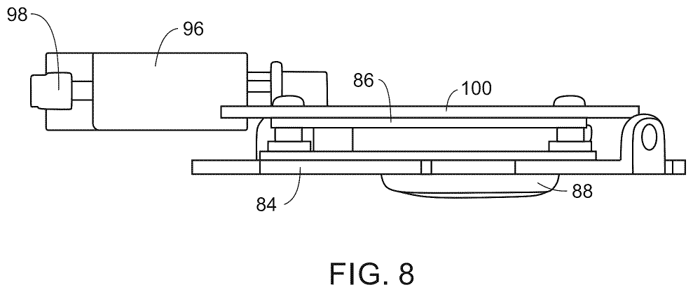

In addition to the engagement flanges 112, the locking bracket 84 includes a pair of locking arms 116 that extend from the main body section 106. The locking arms 116 extend away from the main body section 106 at two of the corners between the end edges 110 and the side edges 108. In the embodiment shown, the locking arms are located 180° from each other. This configuration allows the locking bracket 84 to be used on either side of the front cover. As can best be seen in FIG. 9, each of the locking arms 116 includes a tab 118 that extends perpendicular to the portion of the locking arm 116 that is planar with the main body portion 106. Each tab 118 includes a threaded opening 120 that is sized to receive a threaded shaft of a cap screw or other type of threaded connector. As shown in FIG. 9, the locking bracket 84 includes a button opening 122 that allows the stop button 88 to extend through the main body portion 106. As illustrated in the top view of FIG. 7, the pair of tabs 118 are located approximately the same distance from the center of the stop button 88, even though the locking arms 116 have different lengths. The location of the tabs 118 relative to the stop button 88 again allows the locking bracket 84 to be used on either side of the front cover. Once the combination of the emergency stop assembly 82 and the locking bracket 84 is assembled as shown in FIGS. 7 and 8, the combination is ready for installation on the imaging scanner, such as the MRI scanner shown in the Figures.

The sequence of steps to install the combination of the locking bracket 84 and the emergency stop assembly 82 on the inner surface of the front cover of the MRI scanner will now be described. As indicated previously, the initial step in the installation process is to mount both the receiving plate 58 and the locking assembly 60 to the inner surface 56 of the front cover 18, as is shown in FIG. 5. In the contemplated embodiment, one of the receiving plates 58 and one of the locking assemblies 60 will be mounted to each side of the central bore. Once the receiving plate 58 and the locking assembly 60 are installed on each side of the front cover, the receiving plates 58 are ready to receive one of the locking brackets 84 and one of the emergency stop assemblies 82.

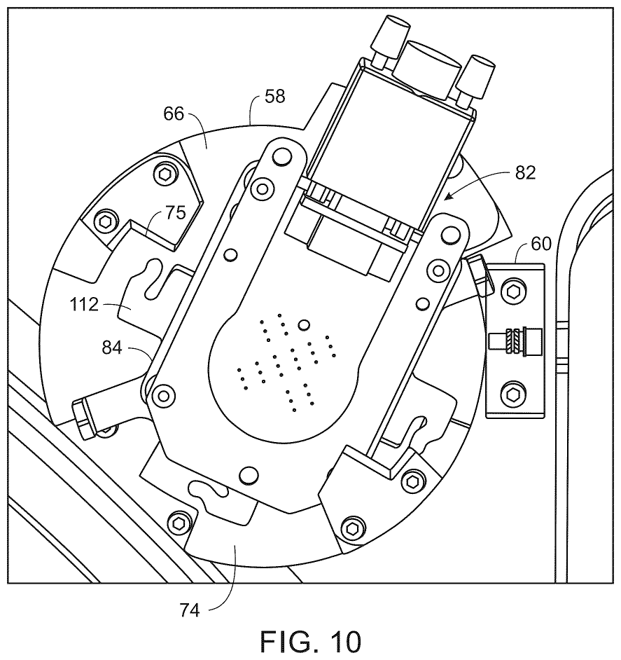

As shown in FIG. 4, the side opening 46 provides an area of access to the installed receiving plate. The installer can reach into the area behind the front wall 48 and begin to install the emergency stop assembly. FIGS. 10-12 illustrate the sequence of steps needed to install the emergency stop assembly. In the initial position shown in FIG. 10, the series of engagement flanges 112 are spaced away from the planar body portion 66 of the receiving plate 58. The engagement flanges 112 are positioned counterclockwise away from the leading edge 75 for each of the receiving slots 73. The position shown in FIG. 10 is the fully released position for the locking bracket 84 since the locking bracket 84 is not engaged with the receiving plate 58 and thus can be moved away from the receiving plate 58.

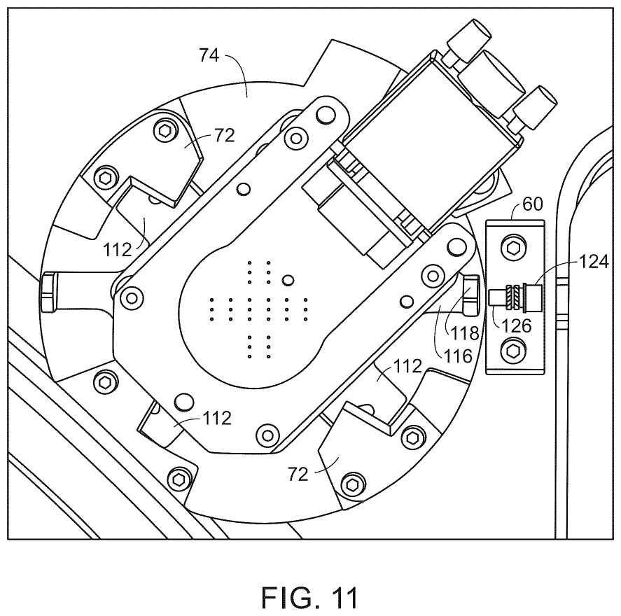

Once in this position, the locking bracket 84 and the attached emergency stop assembly 82 can be moved toward the receiving plate 58 until the engagement flanges 112 contact the top surface 74. In this position, the entire emergency stop assembly 82 and locking bracket 84 can be rotated in the clockwise direction when viewed from above as shown in FIGS. 10 and 11. The clockwise rotation causes each of the engagement flanges 112 to enter into the receiving slot 73 formed between the ears 72 and the top surface 74 of the receiving plate 58. It is contemplated that the locking bracket 84 would need to rotate about 10° in the clockwise direction such that each of the engagement flanges 112 would be received in one of the receiving slot 73. Although not shown, the receiving channel 114 included in each of the engagement flanges 112 receives a post or some other protrusion formed in the receiving slot to help retain the engagement flange in the locking position shown in FIG. 11.

After the locking bracket 84 is rotated into the locking position shown, the symbol 93 on the stop button 88 (FIG. 7) will rotate into the proper orientation such that it is understandable to the user. The receiving plate 58 is oriented on the opposite side of the central bore is a way that the rotation of the locking bracket 84 into the locking position will also cause the symbol 93 to rotate into the proper orientation. In this manner, the locking bracket 84 and receiving plate 58 can be used to mount one of the emergency stop assemblies 82 to each side of the imaging scanner.

When the locking bracket 84 is in the locking position, the outer surface of the stop button 88 is slightly recessed from the outer surface of the front cover. Since the receiving plate 58 is securely mounted to the inner surface of the front cover in a location aligned with the access opening formed in the front cover, the mounting of the receiving plate to the front cover make sure that the stop button 88 is recessed the desired distance (approximately 1 mm) from the outer surface to reduce the chance that the stop button will be accidentally depressed.

In the position shown in FIG. 11, the locking assembly 60 is in the disengaged position. When the locking assembly 60 is in the disengaged position, the locking bracket 84 is freely rotatable, which is required for the initial installation steps described. In the exemplary embodiment shown in FIG. 11, the locking assembly 60 includes a socket head cap screw 124 that includes a threaded shaft 126. However, it is contemplated that the locking assembly 60 could include other elements that can be used to engage the locking bracket 84. In the disengaged position shown in FIG. 11, the threaded shaft 126 is spaced from the tab 118 formed as part of the locking arm 116.

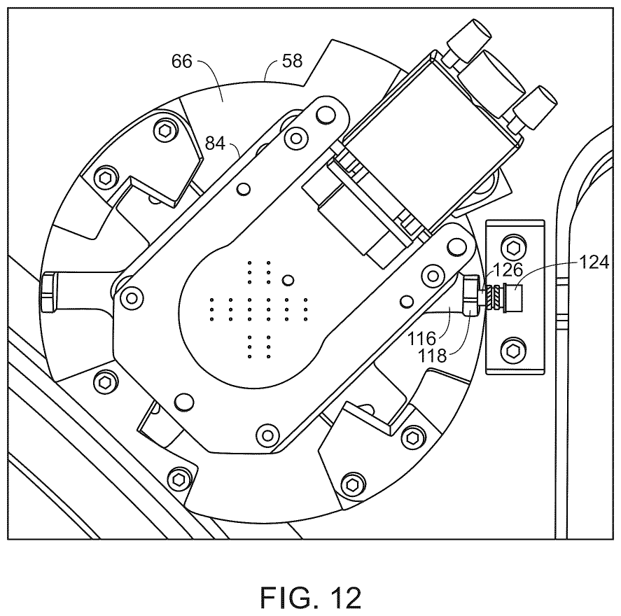

Once the locking bracket is in the locking position of FIG. 11, the locking assembly 60 can be moved to an engaged position, such as is shown in FIG. 12. Specifically, the socket head cap screw 124 is moved forward until the threaded shaft 126 is received in the threaded opening 120 formed in the tab 118. The cap screw 124 is then rotated until the threaded shaft 126 is securely received and retained in the threaded opening 120 of the tab 118. When the locking assembly 60 is in the engaged position, the locking assembly 60 will prevent any unwanted rotation of the locking bracket 84 relative to the stationary receiving plate 58. The locking assembly 60 thus functions as a poka-yoke to lock in the emergency stop assembly 82 in place relative to the receiving plate 58, which is securely attached to the inner surface of the front cover.

If it is desired to remove the emergency stop assembly 82 from the front cover, the steps described to install the emergency stop assembly 82 are reversed. The first step in the removal sequence is to remove the display 20, shroud 24 and the control panel including the buttons 22 that are shown in FIG. 3. Removal of the shroud 24 provides access to the side opening 46 as shown in FIG. 4. Once the user has access to the side opening 46, the user can reach into the space behind the front wall 48 and gain access to the locking assembly 60 that is shown in the engaged position in FIG. 12. When the user has access to the locking assembly 60, the user can rotate the cap screw 124 to disengage the threaded shaft portion 126 from the tab 118. In the embodiment shown and described, the locking assembly 60 is manually operated and thus not controlled by the internal control system of the MRI scanner. Such a manual system is preferred but not required. It is contemplated that the locking assembly 60 could be automatically controlled in other embodiments. Further, it is contemplated that the locking assembly could include other manual engagement mechanisms other than a rotatable cap screw as is illustrated.

After the cap screw 124 is disengaged from the tab 118, as shown in FIG. 11, the user is able to rotate the emergency stop assembly 82 and attached locking bracket 84 in the counterclockwise direction such that the engagement flanges 112 would leave the receiving slots 73, such as shown in FIG. 10. In this release position, the locking bracket 84 can be moved away from the receiving plate 58 and the emergency stop assembly 82 can be completely removed. As part of the removal, the connections 98 on the communication module 96 are disconnected from the control system for the MRI scanner.

This written description uses examples to disclose the invention, including the best mode, and also to enable any person skilled in the art to make and use the invention. Certain terms have been used for brevity, clarity and understanding. No unnecessary limitations are to be inferred therefrom beyond the requirement of the prior art because such terms are used for descriptive purposes only and are intended to be broadly construed. The patentable scope of the invention is defined by the claims, and may include other examples that occur to those skilled in the art. Such other examples are intended to be within the scope of the claims if they have features or structural elements that do not differ from the literal language of the claims, or if they include equivalent features or structural elements with insubstantial differences from the literal languages of the claims.

Unless otherwise specified or limited, the terms “mounted,” “connected,” “linked,” “supported,” and “coupled” and variations thereof are used broadly and encompass both direct and indirect mountings, connections, supports, and couplings. Further, unless otherwise specified or limited, “connected” and “coupled” are not restricted to physical or mechanical connections or couplings. As used herein, unless otherwise limited or defined, discussion of particular directions is provided by example only, with regard to particular embodiments or relevant illustrations. For example, discussion of “top,” “bottom,” “front,” “back,” “left” or “right” features is generally intended as a description only of the orientation of such features relative to a reference frame of a particular example or illustration. Correspondingly, for example, a “top” feature may sometimes be disposed below a “bottom” feature (and so on), depending on the position of the element and the frame of reference. Additionally, use of the words “first,” “second”, “third,” etc. is not intended to connote priority or importance, but merely to distinguish one of several similar elements or machines from another.

We claim:

1. An arrangement for an imaging scanner having a front cover having an outer surface and an inner surface, the arrangement comprising:
a receiving plate attached to the inner surface of the front cover;
an emergency stop assembly configured to communicate with the MRI scanner;
a stop button included as part of the emergency stop assembly, the stop button being operable to cause the emergency stop assembly to initiate an emergency stop procedure upon activation; and
a locking bracket coupled to the emergency stop assembly,
wherein the locking bracket is received by the receiving plate to mount the emergency stop assembly to the inner surface of the front cover such that the stop button is accessible from the outer surface of the front cover.

2. The arrangement of claim 1 wherein the locking bracket is received by the receiving plate and is rotatable relative to the receiving plate between a release position and a locking position.

3. The arrangement of claim 2 wherein the locking bracket includes a plurality of engagement flanges that are each received and retained by the receiving plate when the locking bracket is rotated into the locking position.

4. The arrangement of claim 3 wherein the receiving plate includes a plurality of receiving slots each sized to receive one of the plurality of engagement flanges when the locking bracket is rotated into the locking position.

5. The arrangement of claim 2 further comprising a locking assembly positioned adjacent to the receiving plate and operable to engage the locking bracket to prevent rotation of the locking bracket from the locking position.

6. The arrangement of claim 5 wherein the locking bracket includes at least one locking arm extending from the locking bracket, wherein the locking assembly engages the at least one locking arm to prevent rotation of the locking bracket.

7. The arrangement of claim 6 wherein the locking assembly includes a set screw that is received in a locking tab formed as part of the at least one locking arm.

8. The arrangement of claim 1 wherein the receiving plate includes a central opening sized to allow the stop button to extend through the receiving plate.

9. A method of mounting an emergency stop assembly including a stop button to an imaging scanner having a front cover having an outer surface and an inner surface and one or more display screens, the method comprising the steps of:
attaching a receiving plate to the inner surface of the front cover;
mounting a locking bracket to the emergency stop assembly;
positioning the emergency stop assembly including the locking bracket on the receiving plate; and
rotating the emergency stop assembly and locking bracket into a locking position such that the locking bracket engages the receiving plate to hold the emergency stop assembly on the receiving plate.

10. The method of claim 9 wherein the receiving plate is aligned with an access opening in the front cover prior to attaching the receiving plate to the inner surface of the front cover.

11. The method of claim 10 wherein the stop button extends into the access opening and is accessible from the outer surface of the front cover when the emergency stop assembly and locking bracket are in the locking position.

12. The method of claim 9 further comprising the steps of positioning a locking assembly adjacent to the receiving plate and operating the locking assembly to engage the locking bracket to prevent rotation of the locking bracket from the locking position.

13. The method of claim 12 wherein the locking bracket includes at least one locking arm and the locking assembly engages the at least one locking arm to prevent rotation of the locking bracket.

14. The method of claim 13 wherein the locking assembly includes a set screw that is received in a locking tab formed as part of the at least one locking arm.

15. The method of claim 9 wherein the emergency stop assembly and locking bracket are rotated in a first direction into the locking position and are rotated in a second direction into a release position.

16. The method of claim 9 further comprising the step of removing the one or more display screens from the MRI scanner to provide access to the receiving plate mounted to the inner surface of the front cover.

17. An imaging scanner, comprising:
a front cover having an outer surface and an inner surface;
one or more display screens;
a receiving plate attached to the inner surface of the front cover;
an emergency stop assembly operable to prevent operation of the MRI scanner;
a stop button included as part of the emergency stop assembly, the stop button being operable to cause the emergency stop assembly to initiate an emergency stop procedure upon activation; and
a locking bracket coupled to the emergency stop assembly,
wherein the locking bracket is received by the receiving plate to mount the emergency stop assembly to the inner surface of the front cover such that the stop button is accessible from the outer surface of the front cover.

18. The imaging scanner of claim 17 wherein the locking bracket is received by the receiving plate and is rotatable relative to the receiving plate between a release position and a locking position.

19. The imaging scanner of claim 18 further comprising a locking assembly positioned adjacent to the receiving plate and operable to engage the locking bracket to prevent rotation of the locking bracket from the locking position.

20. The imaging scanner of claim 19 wherein the locking bracket includes at least one locking arm extending from the locking bracket, wherein the locking assembly engages the at least one locking arm to prevent rotation of the locking bracket.
